(19) United States
(12) Patent Application Publication
(10) Pub. No.: US 2022/0353626 A1
(43) Pub. Date: Nov. 3, 2022

(54) Systems, Methods, and Media for Automatically Determining Audio Gain Profiles for Fitting Personal Audio Output Devices

(71) Applicants: The Medical College of Wisconsin, Inc., Miwaukee, WI (US); UWM Research Foundation, Inc., Miwaukee, WI (US)

(72) Inventors: Christina L. Runge, New Berlin, WI (US); Yi Hu, Milwaukee, WI (US)

(21) Appl. No.: 17/601,176

(22) PCT Filed: Apr. 3, 2020
(86) PCT No.: PCT/US2020/026718

§ 371 Date: Oct. 4, 2021

Related U.S. Application Data
(60) Provisional application No. 62/830,087, filed on Apr. 5, 2019.

(51) Int. Cl. H04R 25/00; G06F 3/16

(52) U.S. Cl. CPC H04R 25/505; H04R 25/70; H04R 25/356; H04R 25/30; G06F 3/165; H03G 5/005

(57) ABSTRACT

In accordance with some embodiments, systems, methods and media for automatically determining audio gain profiles for fitting personal audio output devices are provided. In some embodiments, a method for automatically determining audio gain profiles comprises: determining hearing thresholds; determining gain profiles based on the hearing thresholds generating augmented audio signals using the gain profiles; causing the augmented audio signals to be presented using a speaker of an output device; receiving a rating associated with each gain profile; determining fitness values based on the ratings; generating a new generation of gain profiles based on the fitness values, each gain profile comprising bits representing the set of gain values; augmenting the new generation of gain profiles by exchanging a string of bits from a first gain profile with a corresponding string of bits from a second gain profile; and outputting a final gain profile to the output device.

### CROSS-REFERENCE TO RELATED APPLICATIONS

This application is based on, claims the benefit of, and claims priority to, U.S. Provisional Patent Application No. 62/830,087, filed Apr. 5, 2019, which is hereby incorporated herein by reference in its entirety for all purposes.

### STATEMENT REGARDING FEDERALLY SPONSORED RESEARCH

N/A

### BACKGROUND

Despite hearing loss being a very common problem, few adults who could benefit from amplification access such technology, with less than 20% of adults with hearing loss reporting use of hearing aids. Personal sound amplification products (PSAPs) have recently become available to the public, and serve a potentially important role by improving the audibility of sounds for adults that have difficulty hearing and understanding speech in some daily living situations, but who may not be candidates for traditional, high-amplification hearing aids.

In adults, even a mild degree of hearing loss has been associated with increased medical risks such as falling and developing dementia. Among all adults with some degree of hearing loss, adults with mild hearing loss are the least likely to pursue traditional hearing aids despite potential medical co-morbidities. This may be in part due to barriers associated with adoption of hearing technologies, such as high costs of devices and necessary professional care appointments where a medical professional fits (e.g., adjusts one or more physical attributes and/or device settings to improve performance) a hearing device to a patient. For example, costs for hearing aids can range from $1000 to $5000 each, which is often an out-of-pocket expense. PSAPs are a far less expensive option. However, PSAPs typically underperform hearing aids due to a lack of proper fitting, such as selecting appropriate audio gain profiles for the patient in order to amplify frequency bands properly.

Accordingly, systems, methods, and media for automatically determining audio gain profiles for fitting personal audio output devices are desirable.

### SUMMARY

In accordance with some embodiments of the disclosed subject matter, systems, methods, and media for automatically determining audio gain profiles for fitting personal audio output devices are provided.

In accordance with some embodiments of the disclosed subject matter, a system for automatically determining audio gain profiles is provided, the system comprising a computing device comprising at least one processor and a memory, the computing device being in communication with a personal audio output device comprising a speaker, wherein the at least one processor is configured to execute a process comprising: determining a plurality of hearing thresholds based on inputted responses to emitted tones; determining a plurality of gain profiles, each of the plurality of gain profiles based on the plurality of hearing thresholds, each gain profile including a set of gain values; (a) generating a plurality of augmented audio signals by using each of the plurality of gain profiles to augment an audio signal; (b) causing each of the plurality of augmented audio signals to be presented using the speaker; (c) receiving a gain profile rating associated with each of the plurality of gain profiles responsive to causing each of the plurality of augmented audio signals to be presented; (d) determining for each of the plurality of gain profiles a fitness value based on the respective gain profile rating; (e) determining whether a stopping condition has been satisfied; (f) generating a new generation of gain profiles based on fitness values associated with the plurality of gain profiles, wherein each gain profile included in the new generation of gain profiles comprises a plurality of bits representing the set of gain values; (g) in response to determining that at least one stopping condition has not been satisfied, augmenting the new generation of gain profiles by exchanging a string of bits representing at least a portion of one or more gain values in a first gain profile included in the new generation of gain profiles with a corresponding string of bits included in a second gain profile included in the new generation of gain profiles; repeating (a) to (g) until at least one stopping condition has been satisfied at (e) using the new generation of gain profiles generated at (f) and augmented at (g) as the plurality of gain profiles at (a); in response to determining that at least one stopping condition has been satisfied, determining a final gain profile based on the fitness values of the plurality of gain profiles; and outputting the final gain profile to the personal audio output device.

In some embodiments, augmenting the new generation of gain profiles further comprises: randomly mutating at least one bit of a gain value included in one of the gain profiles included in the new generation of gain profiles.

In some embodiments, generating the new generation of gain profiles based on the fitness comprises: performing a plurality of weighted random selections from the plurality of gain profiles with weights based on the fitness value associated with each of the plurality of gain profiles to populate the new generation of gain profiles.

In some embodiments, the audio signal comprises a sentence, and wherein causing each of the plurality of augmented audio signals to be presented using the speaker comprises: causing the sentence to be audibly output by the speaker based on a first gain profile of the plurality of gain profiles; and causing the sentence to be audibly output based on a second gain profile of the plurality of gain profiles, wherein the first current gain profile is associated with a first gain profile rating and the second current gain profile is associated with a second gain profile rating.

In some embodiments, the gain profile ratings are discrete values selected from a predetermined range of values.

In some embodiments, the computing device comprises a smartphone, wherein (a) further comprises retrieving an audio file of the sentence from the memory, and augmenting the audio file based on the first gain profile to produce a first augmented audio signal, and wherein (b) further comprises providing the first augmented audio signal to the personal audio output device, thereby causing the sentence to be audibly output by the speaker.

In some embodiments, the personal audio output device comprises a personal sound amplification product.

In accordance with some embodiments of the disclosed subject matter, a method for automatically determining audio gain profiles is provided, the method comprising: determining a plurality of hearing thresholds based on inputted responses to emitted tones; determining a plurality of gain profiles, each of the plurality of gain profiles based on the plurality of hearing thresholds, each gain profile including a set of gain values; (a) generating a plurality of augmented audio signals by using each of the plurality of gain profiles to augment an audio signal; (b) causing each of the plurality of augmented audio signals to be presented using a speaker of a personal audio output device; (c) receiving, via a user interface, a gain profile rating associated with each of the plurality of gain profiles responsive to causing each of the plurality of augmented audio signals to be presented; (d) determining for each of the plurality of gain profiles a fitness value based on the respective gain profile rating; (e) determining whether a stopping condition has been satisfied; (f) generating a new generation of gain profiles based on fitness values associated with the plurality of gain profiles, wherein each gain profile included in the new generation of gain profiles comprises a plurality of bits representing the set of gain values; (g) in response to determining that at least one stopping condition has not been satisfied, augmenting the new generation of gain profiles by exchanging a string of bits representing at least a portion of one or more gain values in a first gain profile included in the new generation of gain profiles with a corresponding string of bits included in a second gain profile included in the new generation of gain profiles; repeating (a) to (g) until at least one stopping condition has been satisfied at (e) using the new generation of gain profiles generated at (f) and augmented at (g) as the plurality of gain profiles at (a); in response to determining that at least one stopping condition has been satisfied, determining a final gain profile based on the fitness values of the plurality of gain profiles; and outputting the final gain profile to the personal audio output device.

In accordance with some embodiments of the disclosed subject matter, a non-transitory computer readable medium containing computer executable instructions that, when executed by a processor, cause the processor to perform a method for automatically determining audio gain profiles is provided, the method comprising: determining a plurality of hearing thresholds based on inputted responses to emitted tones; determining a plurality of gain profiles, each of the plurality of gain profiles based on the plurality of hearing thresholds, each gain profile including a set of gain values; (a) generating a plurality of augmented audio signals by using each of the plurality of gain profiles to augment an audio signal; (b) causing each of the plurality of augmented audio signals to be presented using a speaker of a personal audio output device; (c) receiving, via a user interface, a gain profile rating associated with each of the plurality of gain profiles responsive to causing each of the plurality of augmented audio signals to be presented; (d) determining for each of the plurality of gain profiles a fitness value based on the respective gain profile rating; (e) determining whether a stopping condition has been satisfied; (f) generating a new generation of gain profiles based on fitness values associated with the plurality of gain profiles, wherein each gain profile included in the new generation of gain profiles comprises a plurality of bits representing the set of gain values; (g) in response to determining that at least one stopping condition has not been satisfied, augmenting the new generation of gain profiles by exchanging a string of bits representing at least a portion of one or more gain values in a first gain profile included in the new generation of gain profiles with a corresponding string of bits included in a second gain profile included in the new generation of gain profiles; repeating (a) to (g) until at least one stopping condition has been satisfied at (e) using the new generation of gain profiles generated at (f) and augmented at (g) as the plurality of gain profiles at (a); in response to determining that at least one stopping condition has been satisfied, determining a final gain profile based on the fitness values of the plurality of gain profiles; and outputting the final gain profile to the personal audio output device.

### BRIEF DESCRIPTION OF THE DRAWINGS

Various objects, features, and advantages of the disclosed subject matter can be more fully appreciated with reference to the following detailed description of the disclosed subject matter when considered in connection with the following drawings, in which like reference numerals identify like elements.

FIG. 1 shows an example of a system for automatically determining audio gain profiles for fitting a personal audio output device in accordance with some embodiments of the disclosed subject matter.

FIG. 2 shows an example of hardware that can be used to implement a personal audio output device, a computing device, and a server in accordance with some embodiments of the disclosed subject matter.

FIG. 3 shows an example of a process for automatically determining audio gain profiles for fitting a personal audio output device in accordance with some embodiments of the disclosed subject matter.

FIG. 4 shows an example of a process for determining hearing thresholds at multiple frequencies in accordance with some embodiments of the disclosed subject matter.

FIG. 5 shows an example of results of a hearing threshold test carried out in accordance with some embodiments of the disclosed subject matter.

FIG. 6 shows an example of a flow of gain profile manipulations performed during a personal audio output device fitting process in accordance with some embodiments of the disclosed subject matter.

FIG. 7 shows an example of a flow of an n-channel amplification that can be performed by a personal audio output device in accordance with some embodiments of the disclosed subject matter.

FIG. 8 shows a graph illustrating a relationship between the number of iterations required for fitting and variance between a starting gain value and a final gain value using an automatic fitting process in accordance with some embodiments of the disclosed subject matter.

FIG. 9 shows an example of a portion of a graphical user interface (GUI) that can be used during determining process for hearing thresholds in accordance with some embodiments of the disclosed subject matter.

FIG. 10 shows an example of a portion of a GUI that can be used to present hearing threshold test results in accordance with some embodiments of the disclosed subject matter.

FIG. 11 shows an example of a portion of a GUI that can be used to accept input for determining a gain profile rating in accordance with some embodiments of the disclosed subject matter.

FIG. 12 shows an example of a portion of a GUI that can be used during determining a process for hearing thresholds in accordance with some embodiments of the disclosed subject matter.

FIG. 13 shows an example of a portion of a GUI that can be used to present personal audio output device fitting instructions in accordance with some embodiments of the disclosed subject matter.

FIG. 14 shows an example of a portion of a GUI that can be used to present results of hearing threshold tests in accordance with some embodiments of the disclosed subject matter.

FIG. 15 shows an example of a portion of a GUI that can be used to select a hearing threshold test as well as an initial fitting technique in accordance with some embodiments of the disclosed subject matter.

FIG. 16 shows an example of a portion of a GUI that can be used to present hearing threshold test instructions in accordance with some embodiments of the disclosed subject matter.

FIG. 17 shows an example of another portion of a GUI that can be used to present results of hearing threshold tests in accordance with some embodiments of the disclosed subject matter.

FIG. 18 shows an example a portion of a GUI that can be used to present audiogram results in accordance with some embodiments of the disclosed subject matter.

FIG. 19 shows an example a portion of a GUI that can be used to select an initial gain profile in accordance with some embodiments of the disclosed subject matter.

FIG. 20 shows an example a portion of a GUI that can be used to present instructions for providing a gain profile rating in accordance with some embodiments of the disclosed subject matter.

FIG. 21 shows an example a portion of a GUI that can be used to provide gain profile ratings in accordance with some embodiments of the disclosed subject matter.

FIG. 22 shows an example a portion of a GUI that can be used to rehabilitate a fitting in accordance with some embodiments of the disclosed subject matter.

FIG. 23 shows an example a portion of a GUI that can be used to initiate an upload of gain profiles to a personal audio output device in accordance with some embodiments of the disclosed subject matter.

FIG. 24 shows an example a portion of a GUI that can be used to access calibration settings in accordance with some embodiments of the disclosed subject matter.

FIG. 25 shows an example a portion of a GUI that can be used to set a calibration volume in accordance with some embodiments of the disclosed subject matter.

FIG. 26 shows an example a portion of a GUI that can be used to present instructions for setting a calibration volume in accordance with some embodiments of the disclosed subject matter.

### DETAILED DESCRIPTION

In accordance with various embodiments, mechanisms (which can, for example, include systems, methods, and media) for automatically determining audio gain profiles for fitting personal audio output devices are provided.

Hearing aids, as well as some PSAPs, can be individually customized via a fitting, which is typically conducting in-person by a medical professional. While such in-person clinical care is considered the gold standard among hearing care professionals, patients do not exhibit the same strong preference for such patient-centered in-person fitting approaches that is exhibited by audiologists. In some embodiments, mechanisms described herein can be used to provide self-directed, home-based amplification interventions that provide fitting results that users of PSAPs prefer to manual fitting, and, perhaps, even find preferable to fitting by an audiologist (e.g., due to the reduced cost and time commitment involved). For example, mechanisms described herein can be implemented within a smartphone application functioning as a PSAP. In such an example, the application can personalize and optimize an amplification profile for individual listeners. With over three-quarters of the US adult population owns a smartphone, including roughly three-quarters of adults aged 50-64 and two-thirds of adults with annual household incomes less than $30,000. With the exceptionally large adoption of smartphone technology across a wide range of demographics, such a smartphone PSAP application has the potential to improve the quality of life of a large segment of US adults.

Recent research indicates that PSAPs vary widely in price and effectiveness. For example, some researchers have measured sentence perception in noise under various conditions including unaided, with a PSAP, and with a hearing aid in older adults with mild to moderate hearing loss. More expensive PSAPs (e.g., an example retailing for about $350) provided benefits approximating those provided by hearing aids with up to 11% improvement over the unamplified condition, while other less expensive PSAPs (e.g., an example retailing for about $30) caused a decrement in performance by 11% compared to the unaided condition. In this study, all devices were fit and adjusted by an audiologist during an in-person appointment that represents a barrier for many patients. User self-fitting is a natural alternative to fitting by an audiologist, which presents a lower barrier as it is more convenient and does not require payment to an experienced audiologist. Conventional approaches to self-fitting generally focus on selecting microphone directionality, ear canal fit, and tubing length. Conventional gain and output settings generally lack personalization and are either based on NAL-NL2 targets for three most common high frequency hearing loss patterns, or a ‘baseline profile’ of prescribed targets based on a users' audiometric thresholds. In some embodiments, mechanisms described herein can provide a user-based, self-fitting optimization procedure in a convenient and accessible smartphone application. In some embodiments, mechanisms described herein can receive feedback compare user-defined performance for unamplified, default prescriptive gain, and user-based fine-tuned gain conditions, and can tune a PSAP based on the feedback in order to increase its effectiveness in aiding the user's hearing. For example, mechanisms described herein can be used to provide a highly marketable and affordable smartphone application that can be used to tune PSAPs for adults. In such an example, the application can facilitate a convenient, affordable, personal amplification option that overcomes current consumer barriers, is personalized and optimized for a user's hearing condition, and can positively impact quality of life and potentially reduce the risk of developing medical comorbidities associated with hearing loss.

Current PSAPs on the market are either pre-programmed with standard algorithms, or have modifiable volume and frequency equalizers that can be manually adjusted by users, who generally lack the experience to determine appropriate settings (e.g., Ear Machine iPhone application, SoundWorld Solutions application). While most PSAPs are not personalized to individuals' thresholds, even those that can be (e.g., SoundWorld Solutions) do not provide user-friendly procedures for personalized fine-tuning and optimization of the sound fitting.

In some embodiments, mechanisms described herein (e.g., implemented using a smartphone, tablet, or other personal computing device) can determine hearing thresholds and gain profiles for a user without the aid of a medical professional. In this way, mechanisms described herein can provide a user with the ability to tune a PSAP in the comfort of their home without traveling to a clinic or other medical facility, and without the significant out of pocket costs that are often associated with fitting by an audiologist.

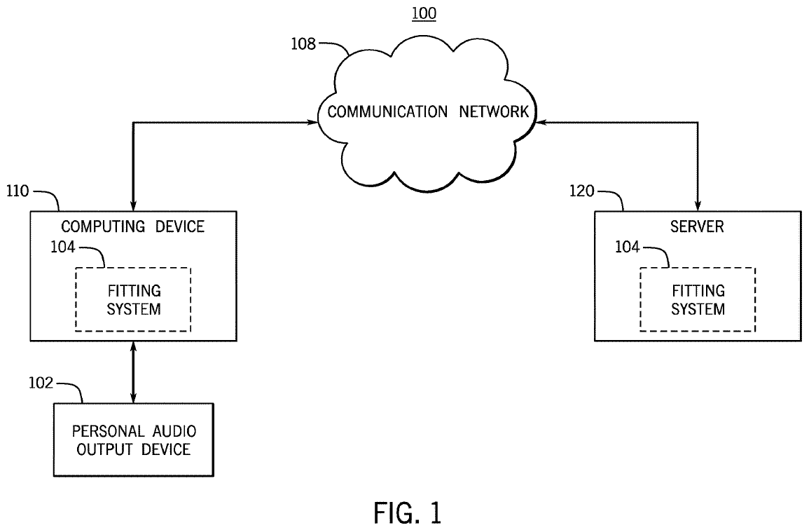

FIG. 1 shows an example 100 of a system for automatically determining audio gain profiles for fitting a personal audio output device in accordance with some embodiments of the disclosed subject matter. As shown in FIG. 1, a computing device 110 can provide tuning parameters and/or audio files to a personal audio output device 102. In some embodiments, personal audio output device 102 can provide gain profile ratings or other preferences as well as device identification information (e.g., model number) to the computing device 110. In some embodiments, computing device 110 can execute at least a portion of a fitting system 104 to automatically fit the personal audio output device 102.

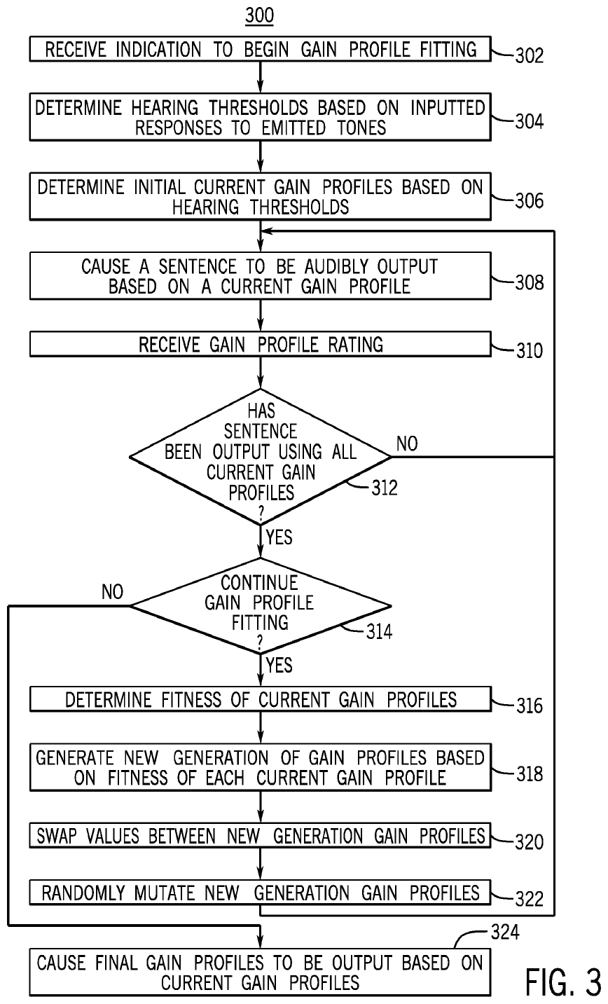

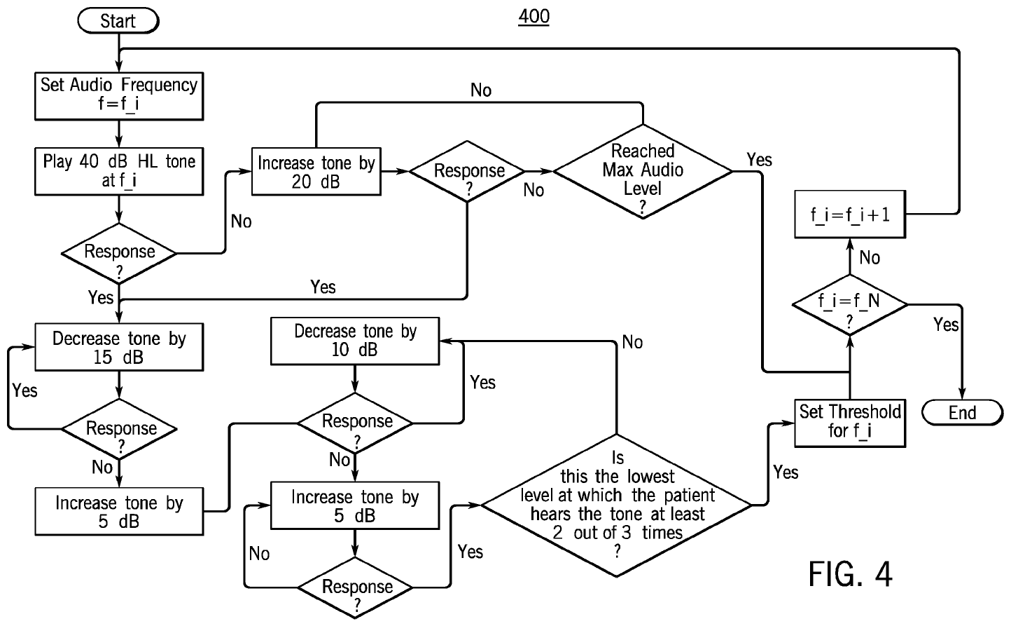

Additionally or alternatively, in some embodiments, computing device 110 can communicate information about data received from personal audio output device 102 to a server 120 over a communication network 108, which can execute at least a portion of fitting system 104 to automatically fit the personal audio output device 102. In such embodiments, server 120 can return information to computing device 110 (and/or any other suitable computing device) indicative of an output of fitting system 104 to automatically fit the personal audio output device 102, such as gain profiles associated with predetermined frequencies, as will be described below, for example, in connection with FIGS. 3 and 4. In some embodiments, computing device 110 and/or server 120 can be any suitable computing device or combination of devices, such as a desktop computer, a laptop computer, a smartphone, a tablet computer, a wearable computer, a server computer, a virtual machine being executed by a physical computing device, etc.

In some embodiments, personal audio output device 102 can be any suitable device capable of providing audio (e.g., to a person), such as personal sound amplification products, wired or wireless headphones, hearing aids, etc. In some embodiments, personal audio output device 102 can be local to computing device 110. For example, personal audio output device 102 can be connected to computing device 110 by a cable, a direct wireless link, etc. Additionally or alternatively, in some embodiments, personal audio output device 102 can be located locally and/or remotely from computing device 110, and can communicate data to computing device 110 (and/or server 120) via a communication network (e.g., communication network 108).

In some embodiments, communication network 108 can be any suitable communication network or combination of communication networks. For example, communication network 108 can include a Wi-Fi network (which can include one or more wireless routers, one or more switches, etc.), a peer-to-peer network (e.g., a Bluetooth network), a cellular network (e.g., a 3G network, a 4G network, etc., complying with any suitable standard, such as CDMA, GSM, LTE, LTE Advanced, WiMAX, etc.), a wired network, etc. In some embodiments, communication network 108 can be a local area network, a wide area network, a public network (e.g., the Internet), a private or semi-private network (e.g., a corporate or university intranet), any other suitable type of network, or any suitable combination of networks. Communications links shown in FIG. 1 can each be any suitable communications link or combination of communications links, such as wired links, fiber optic links, Wi-Fi links, Bluetooth links, cellular links, etc.

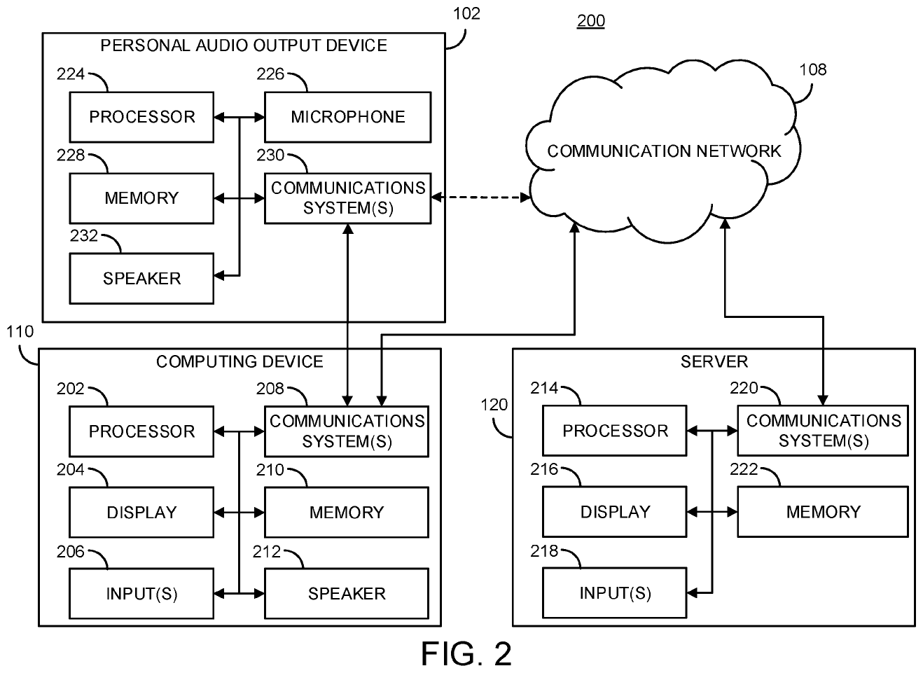

FIG. 2 shows an example 200 of hardware that can be used to implement personal audio output device 102, computing device 110, and server 120 in accordance with some embodiments of the disclosed subject matter. As shown in FIG. 2, in some embodiments, computing device 110 can include a processor 202, a display 204, one or more inputs 206, one or more communication systems 208, memory 210, and/or one or more speakers 212. In some embodiments, processor 202 can be any suitable hardware processor or combination of processors, such as a central processing unit (CPU), a graphics processing unit (GPU), a microcontroller (MCU), an application specific integrated circuit (ASIC), a field programmable gate array (FPGA) etc. In some embodiments, display 204 can include any suitable display devices, such as a computer monitor, a touchscreen, a television, etc. In some embodiments, inputs 206 can include any suitable input devices and/or sensors that can be used to receive user input, such as a keyboard, a mouse, a touchscreen, a microphone, etc.

In some embodiments, communications systems 208 can include any suitable hardware, firmware, and/or software for communicating information over communication network 108 and/or any other suitable communication networks. For example, communications systems 208 can include one or more transceivers, one or more communication chips and/or chip sets, etc. In a more particular example, communications systems 208 can include hardware, firmware, and/or software that can be used to establish a Wi-Fi connection, a Bluetooth connection, a cellular connection, an Ethernet connection, etc.

In some embodiments, memory 210 can include any suitable storage device or devices that can be used to store instructions, values, etc., that can be used, for example, by processor 202 to present content using display 204, to communicate with server 120 via communications system(s) 208, etc. Memory 210 can include any suitable volatile memory, non-volatile memory, storage, or any suitable combination thereof. For example, memory 210 can include RAM, ROM, EEPROM, one or more flash drives, one or more hard disks, one or more solid state drives, one or more optical drives, etc. In some embodiments, memory 210 can have encoded thereon a computer program for controlling operation of computing device 110. In such embodiments, processor 202 can execute at least a portion of the computer program to present content, receive content from server 120, transmit information to server 120, etc.

In some embodiments, speakers 212 can include and/or be associated with any suitable components, such as audio drivers (e.g., one or more 10 millimeter (mm) drivers), and audio output devices (e.g., pre-amplifiers, amplifiers, digital-to-analog converters, etc.).

In some embodiments, server 120 can include a processor 214, a display 216, one or more inputs 218, one or more communications systems 220, and/or memory 222. In some embodiments, processor 214 can be any suitable hardware processor or combination of processors, such as a CPU, a GPU, an MCU, an ASIC), an FPGA, etc. In some embodiments, display 216 can include any suitable display devices, such as a computer monitor, a touchscreen, a television, etc. In some embodiments, inputs 218 can include any suitable input devices and/or sensors that can be used to receive user input, such as a keyboard, a mouse, a touchscreen, a microphone, etc.

In some embodiments, communications systems 220 can include any suitable hardware, firmware, and/or software for communicating information over communication network 108 and/or any other suitable communication networks. For example, communications systems 220 can include one or more transceivers, one or more communication chips and/or chip sets, etc. In a more particular example, communications systems 220 can include hardware, firmware and/or software that can be used to establish a Wi-Fi connection, a Bluetooth connection, a cellular connection, an Ethernet connection, etc.

In some embodiments, memory 222 can include any suitable storage device or devices that can be used to store instructions, values, etc., that can be used, for example, by processor 214 to present content using display 216, to communicate with one or more computing devices 110, etc. Memory 222 can include any suitable volatile memory, non-volatile memory, storage, or any suitable combination thereof. For example, memory 222 can include RAM, ROM, EEPROM, one or more flash drives, one or more hard disks, one or more solid state drives, one or more optical drives, etc. In some embodiments, memory 222 can have encoded thereon a server program for controlling operation of server 120. In such embodiments, processor 214 can execute at least a portion of the server program to transmit information and/or content (e.g., gain profile values, etc.) to one or more computing devices 110, receive information and/or content from one or more computing devices 110, receive instructions from one or more devices (e.g., a personal computer, a laptop computer, a tablet computer, a smartphone, etc.), etc.

In some embodiments, personal audio output device 102 can include a processor 224, a microphone 226, memory 228, one or more communications systems 230, and/or one or more speakers 232. In some embodiments, processor 224 can be any suitable hardware processor or combination of processors, such as a CPU, a GPU, an MCU, an ASIC, an FPGA, etc. In some embodiments, microphone 226 can be any suitable microphone, such as a USB microphone, an on-board microphone (e.g., on-board a microchip), etc. In some embodiments, microphone 226 can be omitted. For example, microphone 226 can be omitted when a microphone of computing device 110 is used to pick up audio to amplified and presented via speaker 232.

Note that, although not shown, personal audio output device 102 can include any suitable inputs and/or outputs. For example, personal audio output device 102 can include input devices and/or sensors that can be used to receive user input, such as buttons, touchscreens, etc. As another example, personal audio output device 102 can include any suitable display devices, such as a touchscreen, LEDs, etc.

In some embodiments, memory 228 can include any suitable storage device or devices that can be used to store instructions, values, etc., that can be used, for example, by processor 224 to: control microphone 226, and/or receive data from microphone 226; communicate with one or more computing devices 110; etc. Memory 228 can include any suitable volatile memory, non-volatile memory, storage, or any suitable combination thereof. For example, memory 228 can include RAM, ROM, EEPROM, one or more flash drives, one or more hard disks, one or more solid state drives, one or more optical drives, etc. In some embodiments, memory 228 can have encoded thereon a program for controlling operation of personal audio output device 102. In such embodiments, processor 224 can execute at least a portion of the program to transmit information and/or content (e.g., an audio bit stream) to one or more computing devices 110, receive information and/or content from one or more computing devices 110, receive instructions from one or more devices (e.g., a personal computer, a laptop computer, a tablet computer, a smartphone, etc.), etc.

In some embodiments, communications systems 230 can include any suitable hardware, firmware, and/or software for communicating information over communication network 108 and/or any other suitable communication networks. For example, communications systems 230 can include one or more transceivers, one or more communication chips and/or chip sets, etc. In a more particular example, communications systems 230 can include hardware, firmware and/or software that can be used to establish a wired connection using any suitable port and/or communication standard (e.g., USB, RS-232, etc.), Wi-Fi connection, a Bluetooth connection, a cellular connection, an Ethernet connection, etc.

In some embodiments, speakers 232 can include and/or be associated with any suitable components, such as audio drivers (e.g., one or more 10 millimeter (mm) drivers), and audio output devices (e.g., pre-amplifiers, amplifiers, digital-to-analog converters, etc.).

FIG. 3 shows an example of a process 300 for automatically determining audio gain profiles for fitting a personal audio output device in accordance with some embodiments of the disclosed subject matter. In some embodiments, fitting system 104 can execute one or more portions of process 300.

At 302, process 300 can receive an indication to begin gain profile setting. In some embodiments, process 300 can receive the indication from any suitable device, such as the computing device 110 and/or the server 120 described above in connection with FIG. 1.

At 304, process 300 can determine hearing thresholds based on inputted responses to emitted hearing tones. In some embodiments, process 300 can cause a hearing threshold test to be conducted in order to determine hearing thresholds of a user at a number of frequencies. For example, in some embodiments, process 300 can determine thresholds for a number of frequencies including 500 Hz, 1000 Hz, 2000 Hz, 4000 Hz, and 6000 Hz. In such an example, process 300 can cause tones to be emitted at each frequency, and vary the sound pressure level (SPL) of the tones in order to determine the minimum SPL at which the user can perceive the tones by prompting the user to provide input indicating when the tone is perceived. In some embodiments, process 300 can set the hearing thresholds equal to the minimum SPL for each frequency. In some embodiments, process 300 can execute the process described below in connection with FIG. 4 at 304.

Note that background noise in the room may confound hearing threshold testing, which is why audiologists generally conduct hearing threshold testing in quiet controlled environment. In some embodiments, room noise levels can be monitored using a sound level meter and, if necessary, background noise interference can be monitored and mitigated.

At 306, process 300 can determine a set of initial gain profiles to use based on the hearing thresholds. In some embodiments, process 300 can determine an initial gain profile based on the hearing thresholds using any suitable technique or combination of techniques. For example, process 300 can use one or more techniques for determining an initial gain profile described by National Acoustics Laboratories (NAL), such as techniques described in connection with protocols referred to as NAL-NL1, and NAL-NL2. In some embodiments, process 300 can use one or more techniques for determining an initial gain profile described in connection with protocols often referred to as Desired Sensation Level (DSL).

In some embodiments, process 300 can determine additional gain profiles by randomly mutating (e.g., adding noise) to the initial gain profile. The set of initial gain profiles determined at 306 are sometimes referred to as current gain profiles. Each gain profile can include gain values for various frequency bands, such as 0-2000 Hz, 2000-4000 Hz, 4000-6000 Hz, and 6000-8000 Hz.

At 308, process 300 can cause a sentence to be audibly output based on a gain profile included in the set of current gain profiles. In some embodiments, the gain profile can be selected from the current gain profiles by selecting a gain profile that has not been used to audibly output the sentence (e.g., randomly, in a pre-selected order). Process 300 can cause the sentence to be audibly output by the personal audio output device 102 (e.g., using the speakers 232) using the selected gain profile. For example, process 300 can cause the personal audio output device 102 to amplify the sentence (e.g., the original audio file) based on the selected gain profile. In some embodiments, the process 300 retrieve an audio file of the sentence from memory, augment the audio file based on the selected gain profile, and provide the augmented audio file to the personal audio output device 102. The personal audio output device 102 can audibly output the augmented audio file. In some embodiments, the computing device 110 can execute at least a portion of the process 300 to retrieve an audio file of the sentence from memory, augment the audio file based on the selected gain profile, and provide the augmented audio file to the personal audio output device 102.

At 310, process 300 can receive a gain profile rating. In some embodiments, the gain profile rating can be a rating associated with the gain profile used to amplify the sentence output at 308. In some embodiments, process 300 can receive the gain profile rating from any suitable device, such as the computing device 110. In some embodiments, the rating can be in any suitable format. For example, the rating can be provided as a selection from a number of predetermined ratings (e.g., poor, medium, good, great, etc.). As another example, the rating can be provided as a numerical value on a scale (e.g., a scale of 1-5, 1-10, 0-4, etc.). As yet another example, the rating can be provided as a ranking (e.g., by ranking which of multiple versions of the sentence was best, worst, second best, etc.).

At 312, process 300 can determine if every gain profile in the set of current gain profiles has been used to cause the sentence to be audibly output based (e.g., at 308). If every gain profile in the current gain profiles has been used at 308 (e.g., “YES” at 312), process 300 can proceed to 314. If not every gain profile in the current gain profiles has been used at 308 (e.g., “NO” at 312), process 300 can proceed to 308.

At 314, process 300 can determine if gain profile fitting should continue. In some embodiments, process 300 can use one or more stopping conditions to determine if gain profile fitting should continue. For example, in some embodiments, process 300 can determine if a minimum number of gain profiles have been tested, and if the minimum has not been reached, process 300 can determine that profile fitting should continue. As another example, in some embodiments, process 300 can determine if a maximum number of gain profiles have been tested, and if the maximum has not been reached, process 300 can determine that profile fitting should not continue, unless another stopping condition has been satisfied. As yet another example, in some embodiments, if at least one the gain profile rating associated with the set of current gain profiles is above a threshold (e.g., received a rating of at least “great”), process 300 can determine that gain profile fitting can end. As still another example, if there are no gain profile ratings associated with the set of current gain profiles that are above a threshold (e.g., received a rating of at least “great”), process 300 can determine that gain profile fitting should continue. If process 300 determines that the gain profile fitting should continue (e.g., “YES” at 314), process 300 can proceed to 316. Otherwise, if process 300 determines that the gain profile fitting should not continue (e.g., “NO” at 314), process 300 can proceed to 324.

At 316, process 300 can determine a fitness value for each gain profile of the set of current gain profiles. Process 300 can determine the fitness of the each current gain profile based on the gain profile rating associated with the current gain profile. The fitness can be a number, with higher number indicating higher fitness. The fitness of current gain profiles with relatively higher gain profile ratings (e.g., “good”) can be higher than the fitness of current gain profiles with relatively lower ratings (e.g., weak).

At 318, process 300 can generate a new generation of gain profiles based on the fitness of each current gain profile. In some embodiments, process 300 can populate the new generation gain profiles by performing a weighted random selection of the current gain profiles based on the fitness of each current gain profile. For example, for each new generation gain profile, process 300 can select one of the current gain profiles in a process in which current gain profiles with higher fitness are more likely to be selected (which can sometimes be referred to as a “roulette” process). Process 300 can then set the gain values of the new generation gain profile to be equal to the selected current gain profile. Some new generation gain profiles can share the same gain values.

At 320, process 300 can swap gain values between the new generation of gain profiles. In some embodiments, process 300 can randomly select at least one pair of gain profiles at a predetermined occurrence rate. In some embodiments, each pair of gain profiles within the new generation of gain profiles can have a predetermined chance of being selected (e.g., a ten percent chance). In some embodiments, if any pairs of gain profiles are selected, process 300 can select a range of values within each pair of gain profiles to begin exchanging values, and then exchange gain values. For example, each new generation gain profile can have four gain values corresponding to four respective frequency bands. Process 300 can select a first new generation gain profile and a second new generation gain profile. Process 300 can then select a range of values in the gain values to swap, such as the gain values associated with the first and second frequency bands. Process 300 can then exchange the gain values associated with the first and second frequency bands in the first new generation gain profile with the gain values associated with the first and second frequency bands in the second new generation gain profile. In some embodiments, process 300 can select the range by randomly determining a starting point and a stopping point in the binary representations of the gain values. For example, each gain value can be represented as a six bit binary number. In a more particular example, if process 300 determines that the starting point is the fourth bit of the first gain value and the stopping point is the third bit of the third gain value, process 300 can then exchange the bits ranging from the fourth bit of the first gain value to the third bit of the third gain value in the first new generation gain profile with the bits ranging from the fourth bit of the first gain value to the third bit of the third gain value in the second new generation gain profile.

At 322, process 300 can randomly mutate the new generation of gain profiles. In some embodiments, process 300 can randomly select one or more bits included in the gain values of any of the new generation gain profiles, and flip the bit (e.g., change a “1” to a “0” or a “0” to a “1”). Process 300 can return to 308, cause sentences to be audibly output based on the current gain profiles, and receive gain profile ratings for the current gain profiles. Process 300 can then determine whether or not to continue fitting gain profiles and generate a new generation of gain profiles, or whether to output the current gain profiles. Note that once the new generation gain profiles have been finalized at 322, they are referred to as the current gain profiles.

At 324, process 300 can output final gain profiles. The final gain profiles can be the current gain profiles. The final gain profiles can be output to a personal audio output device (e.g., personal audio output device 102). The final gain profiles can be used to set the amplification levels at frequency bands in audio output by the personal audio output device.

FIG. 4 shows an example of a process 400 for determining hearing thresholds at multiple frequencies in accordance with some embodiments of the disclosed subject matter. In some embodiments, process 400 can be used to determine hearing thresholds, as described above in connection with 304 in process 300 in FIG. 3. Process 400 can determine hearing thresholds for frequencies f_i to f(i+n). After playing a tone at f_i, process 400 can determine if a response was received within a predetermined amount of time, indicating that the user heard the tone (e.g., at “Response?” decision diamonds). Based on whether or not a response was received indicating that the user heard the tone, process 400 can either increase or decrease the SPL of the tone. Process 400 can limit the SPL to a maximum SPL level, such as 110 dB. When a lowest SPL at which the user can hear the tone two out of three times has been determined, process 400 can set the threshold for f_i. Process 400 can continue until either a maximum audio level has been reached or a threshold has been determined for all frequencies f_i to f_(i+n). In some embodiments, process 400 can include at least a portion of a Hughson-Westlake Method. In some embodiments, if the user's threshold corresponds to 25 dB of hearing loss at any frequency, process 400 can cause a warning to be presented indicating to the user they may have hearing loss and recommending an evaluation by a hearing professional.

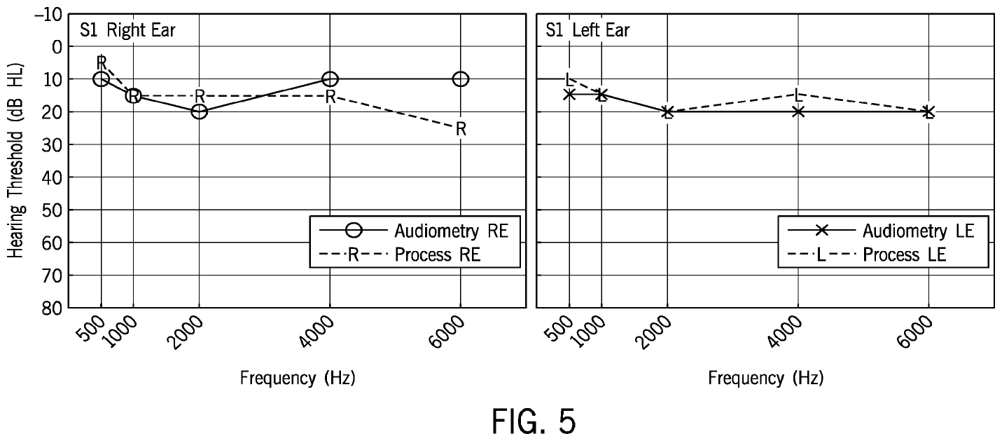

FIG. 5 shows an example of results of a hearing threshold test carried out in accordance with some embodiments of the disclosed subject matter. The results were collected from the right and left ears of a 52-year-old male subject with bilateral borderline normal hearing who noted difficulty in most noisy situations. Threshold testing was performed for standard air-conduction audiometric testing by an audiologist in a sound booth, and using process 400 with earbuds in a quiet room (background noise levels were unmonitored for this subject). Testing was performed for frequencies of 500 Hz, 1000 Hz, 2000 Hz, 4000 Hz, and 6000 Hz. For the right ear, hearing thresholds were within 5 dB of audiometric thresholds for all frequencies except 6000 Hz, which was elevated by 15 dB. For the left ear, thresholds determined by process 400 were within 5 dB of audiometric thresholds for all frequencies. FIG. 5 shows that process 400 was capable of measuring hearing thresholds at the five frequencies tested using earbuds with comparable accuracy to a trained audiologist.

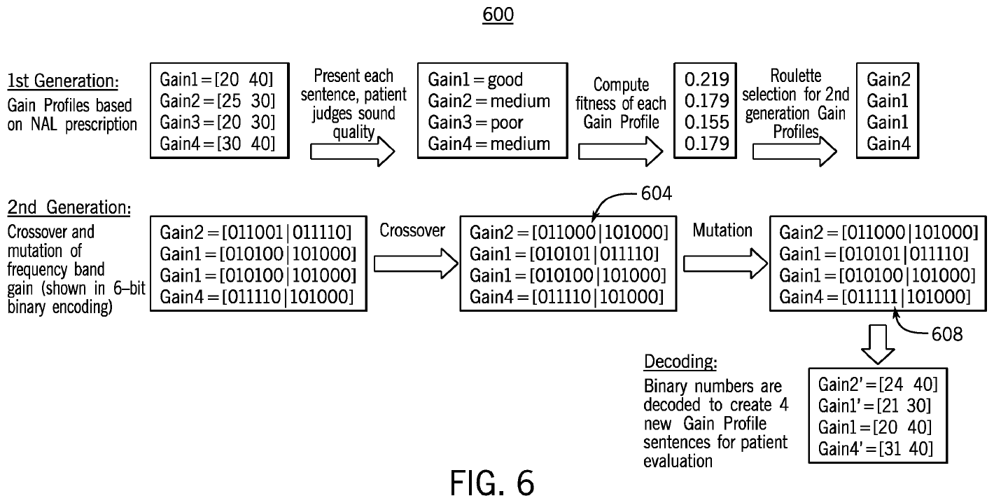

FIG. 6 shows an example of a flow 600 of gain profile manipulations performed during a personal audio output device fitting process in accordance with some embodiments of the disclosed subject matter. In some embodiments, flow 600 can be used to determine hearing thresholds, as described above in connection with 310 and 316-322 in process 300 of FIG. 3. As shown in FIG. 6, flow 600 can include receiving gain profile ratings associated with a number of gain profiles, such as four gain profiles (e.g., at 310 in process 300). The gain profiles can include a number of gain values associated with a number of frequency bands. As shown in FIG. 6, to illustrate the concepts without overcrowding the figure, each gain profile includes two six bit gain values, but this is merely an example and gain profiles can include any suitable number of gain values. Flow 600 can include determining fitness of each gain profile based on the gain profile rating associated with each gain profile (e.g., at 316 in process 300). Flow 600 can include generating second generation gain profiles (e.g., new current gain profiles) based on the fitness of each gain profile (e.g., at 318 in process 300). The flow can include crossover (e.g., swapping) of bits between gain profiles (e.g., at 320 in process 300). Flow 600 can select a starting bit 604 at which to being swapping bits. As shown, the starting bit 604 can be the first bit in a first gain value. Flow 600 can swap every bit ranging from the first bit in the first gain value to the first bit in the second gain value for two randomly selected gain profiles, such as the first current gain profile and the second current gain profile. Flow 600 can include randomly mutating at least one bit in the current gain profiles (e.g., at 322 in process 300). As shown, flow 600 can mutate (e.g., flip) a bit 608 included in the first gain value of the fourth current gain profile. Flow 600 can include decoding the binary gain profiles into integers.

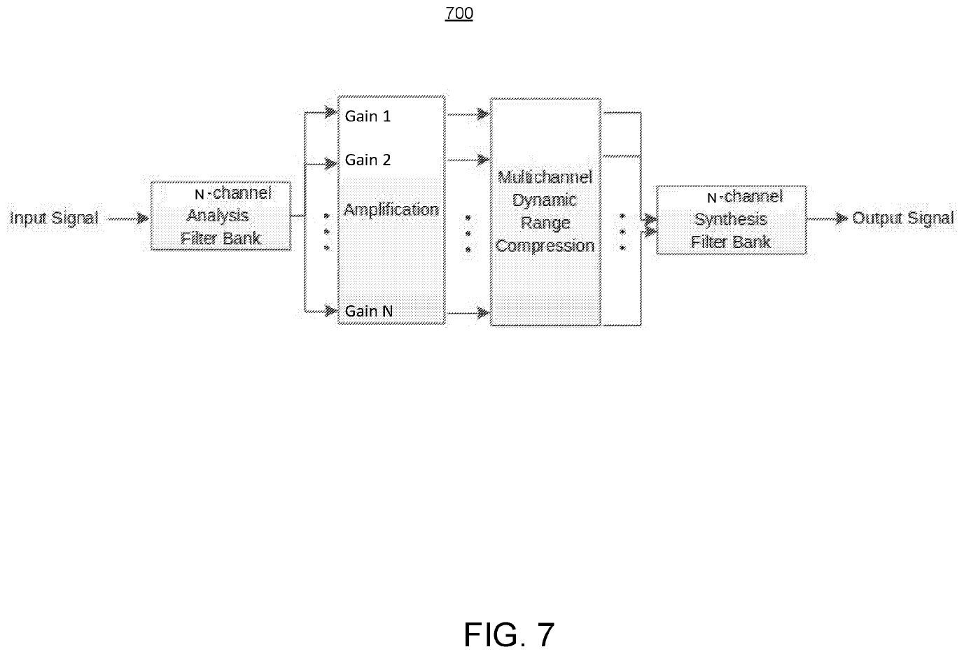

FIG. 7 shows an example of a flow 700 of an n-channel amplification that can be performed by a personal audio output device in accordance with some embodiments of the disclosed subject matter. Flow 700 can include dividing an input signal into a number of channels, each channel associated with a frequency band using a filter bank. Flow 700 can include amplifying each channel by a predetermined gain value (e.g., a gain value included in a gain profile generated by process 300). Flow 700 can include compressing the channels and synthesizing the channels into an output signal using a filter bank. The output signal can then be audibly output at speakers.

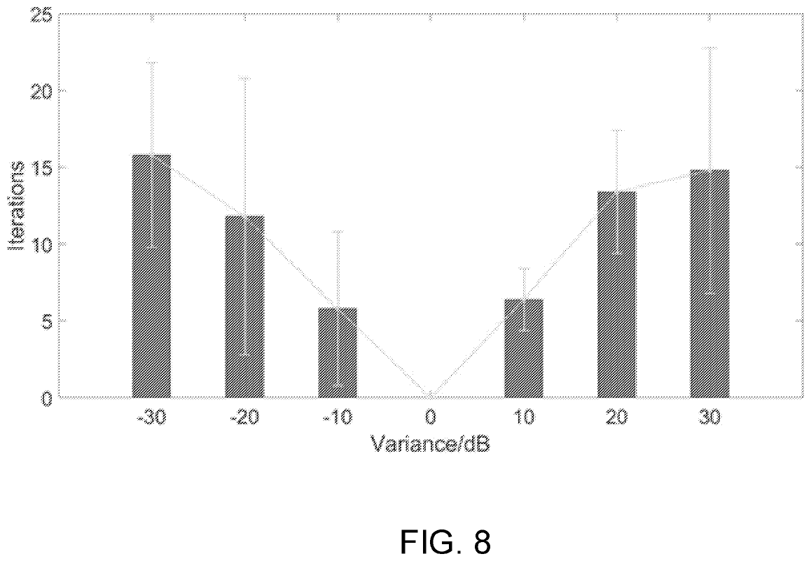

FIG. 8 shows a graph illustrating a relationship between the number of iterations required for fitting and variance between a starting gain value and a final gain value using an automatic fitting process in accordance with some embodiments of the disclosed subject matter. For this experiment, six sets of frequency-band start-gain values (−30 dB, −20 dB, −10 dB, 10 dB, 20 dB, 30 dB) were evaluated. Overall, greater differences between start gain values and optimal levels required more iterations to converge. When the five frequency-band gain values started at ±30 dB, it took an average of 16 iterations and approximately eight minutes for the proposed algorithm to converge to values with −5 and 5 dB. In some embodiments, process 300 in FIG. 3 can converge on optimal settings with <16 iterations in <8 minutes, indicative of process 300 being usable in the real world.

Table 1 below shows results of fitting of five patients performed using a system implemented in accordance with some embodiments of the disclosed subject matter All five subjects were able to provide feedback (e.g., gain profile ratings) for use in process 300, and process 300 successfully measured hearing thresholds, and showed a difference in gain values between initial settings and self-fitting. All five subjects preferred the sound quality of the self-fitting gain compared to the initial gain, indicating success of the system implemented in accordance with some embodiments of the disclosed subject matter in improving sound quality for individual listeners.

TABLE 1

| | | | | | | Gain | Self- |
|---|---|---|---|---|---|---|---|
| | | | Thresh- | Initial | Self- | Differ- | Fitting |
| Sub- | | Fre- | old | Fitting | Fitting | ence | Time |
| ject | Age | quency | (dB | Gain | Gain | (+Is | (Min- |
| # | (Years) | (Hz) | HL) | (dB) | (dB) | Louder) | utes) |
| 1 | 49 | 500 | 5 | 2 | 7 | 5 | 5.7 |
| | | 1000 | 15 | 2 | −8 | −10 | |
| | | 2000 | 15 | 3 | −2 | −5 | |
| | | 4000 | 18 | −3 | −8 | −5 | |
| | | 6000 | 5 | 2 | −3 | −5 | |
| 2 | 54 | 500 | 20 | 2 | 7 | 5 | 4.2 |
| | | 1000 | 30 | 12 | 12 | 0 | |
| | | 2000 | 25 | 8 | 3 | −5 | |
| | | 4000 | 25 | 2 | 7 | 0 | |
| | | 6000 | 10 | 2 | −8 | −15 | |
| 3 | 38 | 500 | 20 | 2 | 7 | 5 | 6.1 |
| | | 1000 | 30 | 12 | 2 | −10 | |
| | | 2000 | 25 | 8 | 3 | 5 | |
| | | 4000 | 25 | 2 | −3 | −5 | |
| | | 6000 | 10 | 2 | −8 | −10 | |
| 4 | 38 | 500 | 13 | 6 | −4 | −10 | 5.28 |
| | | 1000 | 23 | 9 | −0.5 | −9.5 | |
| | | 2000 | 20 | 7 | −3 | −10 | |
| | | 4000 | 7 | 2 | −3 | −5 | |
| | | 6000 | 15 | 9 | 4 | −5 | |
| 5 | 39 | 500 | 15 | 5 | −14 | −19 | 8.7 |
| | | 1000 | 20 | 10 | 10 | 0 | |
| | | 2000 | 30 | 12 | 2 | −10 | |
| | | 4000 | 50 | 18 | 13 | −5 | |
| | | 6000 | 35 | 13 | 18 | 5 | |

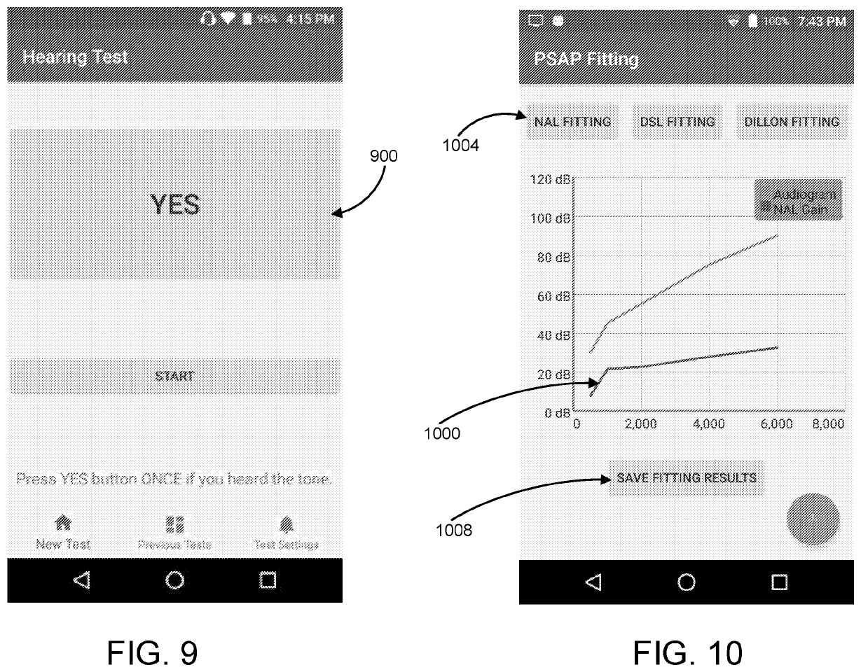

FIG. 9 shows an example of a portion of a graphical user interface (GUI) that can be used during determining process for hearing thresholds in accordance with some embodiments of the disclosed subject matter. In some embodiments, process 300 of FIG. 3 can cause the GUI of FIG. 9 to be presented at 304. In some embodiments, the GUI can include a user interface element 900 (associated with text “YES” in FIG. 9) that can be used selected to indicate that a user heard a tone.

FIG. 10 shows an example of a portion of a GUI that can be used to present hearing threshold test results in accordance with some embodiments of the disclosed subject matter. In some embodiments, process 300 of FIG. 3 can cause the GUI of FIG. 10 to be presented at 306. In some embodiments, process 300 can generate a gain curve 1000 for frequency-specific amplification requirements based on the threshold results of a hearing threshold test. In some embodiments, the gain curve 1000 can be generated using a fitting formula such as a NAL formula or a DSL formula. In some embodiments, the GUI can include a number of selected user interface elements, such as user interface element 1004 that can be used to receive a fitting technique selection (e.g., NAL, DSL, Dillon, etc.). In some embodiments, the GUI can include a user interface element 1008 that can be used to receive an indication to save the selected fitting technique and/or the gain curve 1000.

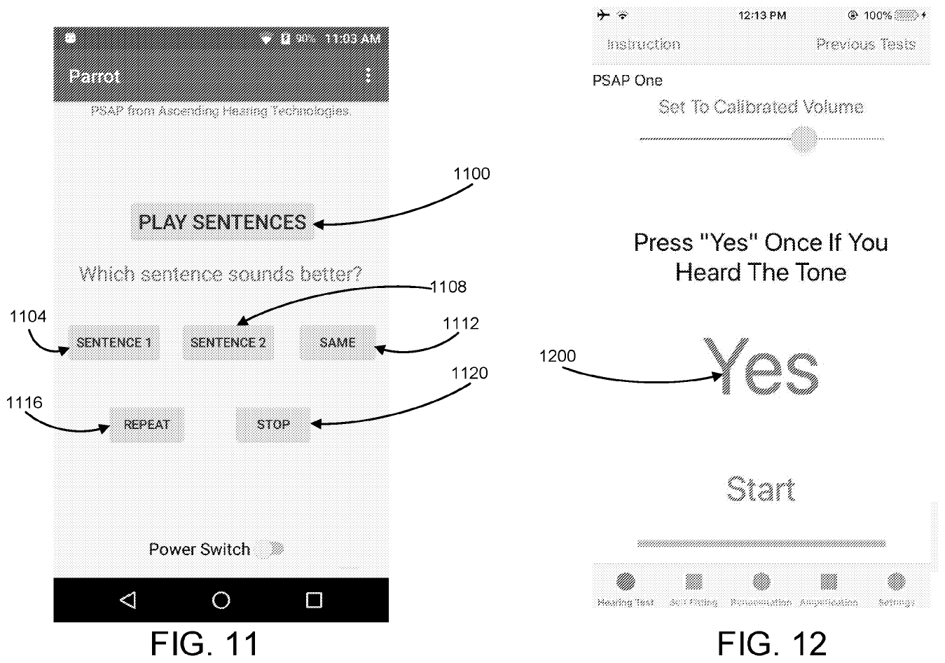

FIG. 11 shows an example of a portion of a GUI that can be used to accept input for determining a gain profile rating in accordance with some embodiments of the disclosed subject matter. In some embodiments, process 300 of FIG. 3 can cause the GUI of FIG. 11 to be presented at 310. In some embodiments, the GUI can include a user interface element 1100 that can be used to receive an indication to play (e.g., audibly) a sentence. In some embodiments, the GUI can include a user interface element 1104 that can be used to receive an indication that a first sentence sounded better than a second sentence. In some embodiments, the GUI can include a user interface element 1108 that can be used to receive an indication that the second sentence sounded better than the first sentence. In some embodiments, the GUI can include a user interface element 1112 that can be used to receive an indication that the second sentence sounds about the same as the first sentence. In some embodiments, the GUI can include a user interface element 1116 that can be used to receive an indication to play the first sentence and the second sentence again. In some embodiments, the GUI can include a user interface element 1120 that can be used to receive an indication to stop a fitting process.

FIG. 12 shows an example of a portion of a GUI that can be used during determining process for hearing thresholds in accordance with some embodiments of the disclosed subject matter. In some embodiments, process 300 of FIG. 3 can cause the GUI of FIG. 12 to be presented at 304. In some embodiments, the GUI can include a user interface element 1200 that can be used to receive an indication that a tone was heard.

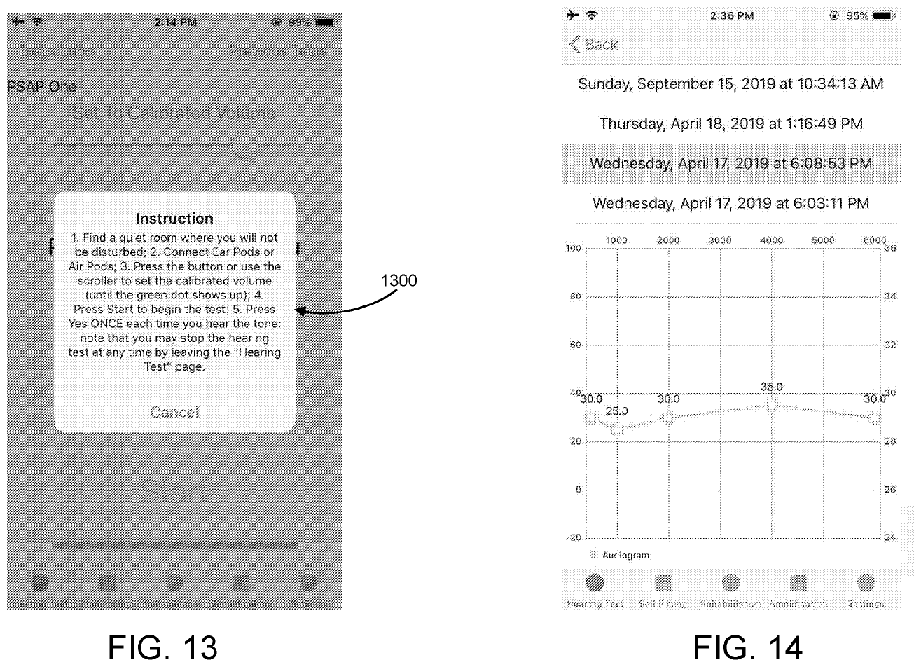

FIG. 13 shows an example of a portion of a GUI that can be used to present personal audio output device fitting instructions in accordance with some embodiments of the disclosed subject matter. In some embodiments, process 300 of FIG. 3 can cause the GUI screen of FIG. 13 to be presented at 304. In some embodiments, the GUI can include an instructions module 1300 that can include instructions on how to conduct a hearing threshold test.

FIG. 14 shows an example of a portion of a GUI that can be used to present results of hearing threshold tests in accordance with some embodiments of the disclosed subject matter. In some embodiments, process 300 of FIG. 3 can cause the GUI of FIG. 14 to be presented at 306.

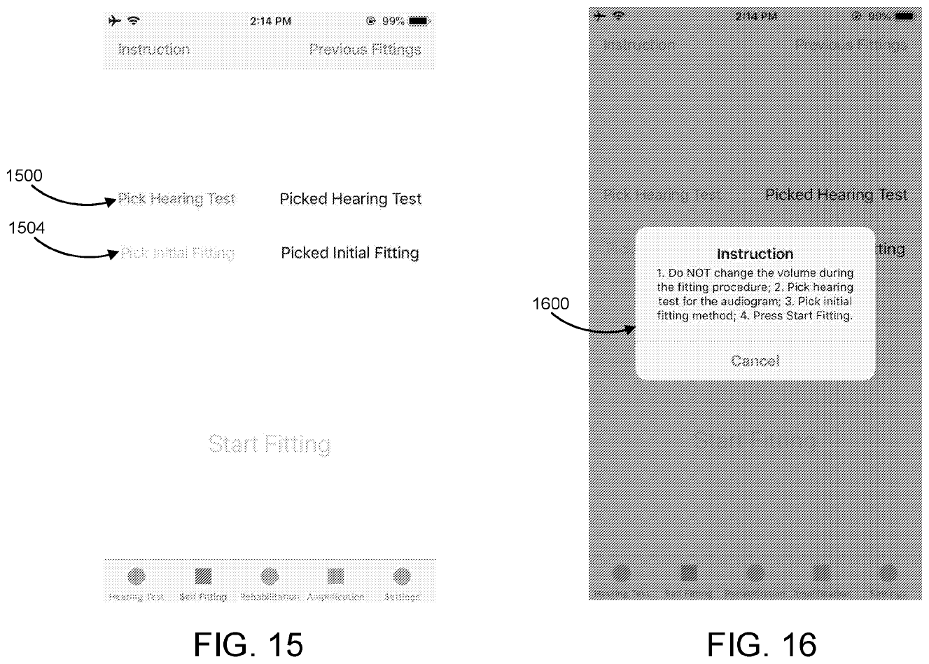

FIG. 15 shows an example of a portion of a GUI that can be used to select a hearing threshold test as well as an initial fitting technique in accordance with some embodiments of the disclosed subject matter. In some embodiments, process 300 of FIG. 3 can cause the GUI of FIG. 15 to be presented at 306. In some embodiments, the GUI can include a user interface element 1500 that can receive an indication that a user would like to select a hearing test. In some embodiments, the GUI can include a user interface element 1504 that can be used to receive an indication that a user would like to select initial gain profiles based on a fitting technique such as NAL, DSL, Dillon, etc.

FIG. 16 shows an example of a portion of a GUI that can be used to present hearing threshold test instructions in accordance with some embodiments of the disclosed subject matter. In some embodiments, process 300 of FIG. 3 can cause the GUI of FIG. 16 to be presented at 306. In some embodiments, the GUI can include an instructions module 1600 that can include instructions on how to conduct a gain profile fitting process.

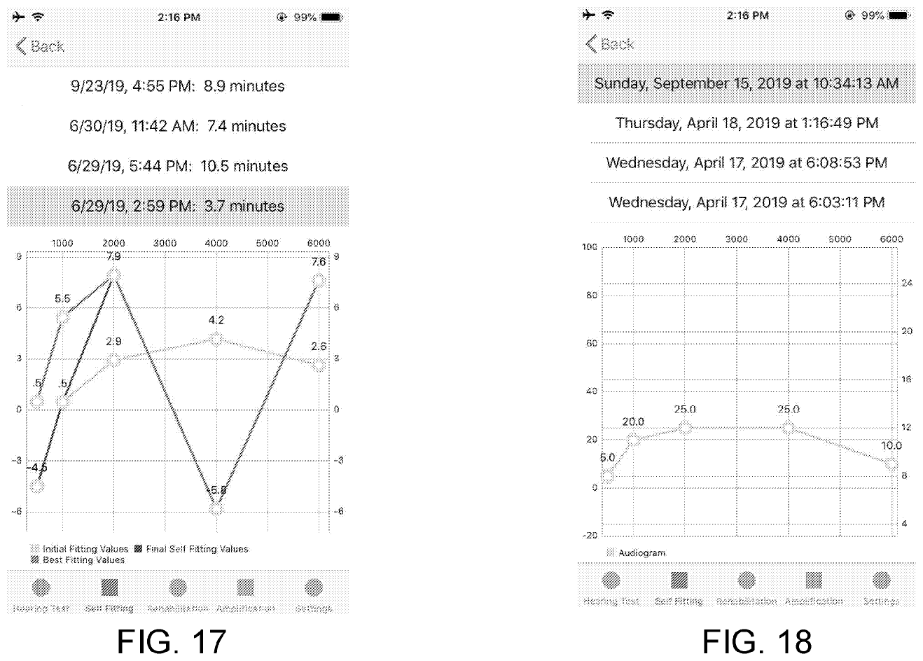

FIG. 17 shows an example of another portion of a GUI that can be used to present results of hearing threshold tests in accordance with some embodiments of the disclosed subject matter. In some embodiments, process 300 of FIG. 3 can cause the GUI of FIG. 10 to be presented at 306.

FIG. 18 shows an example a portion of a GUI that can be used to present audiogram results in accordance with some embodiments of the disclosed subject matter. In some embodiments, process 300 of FIG. 3 can cause the GUI of FIG. 18 to be presented at 306.

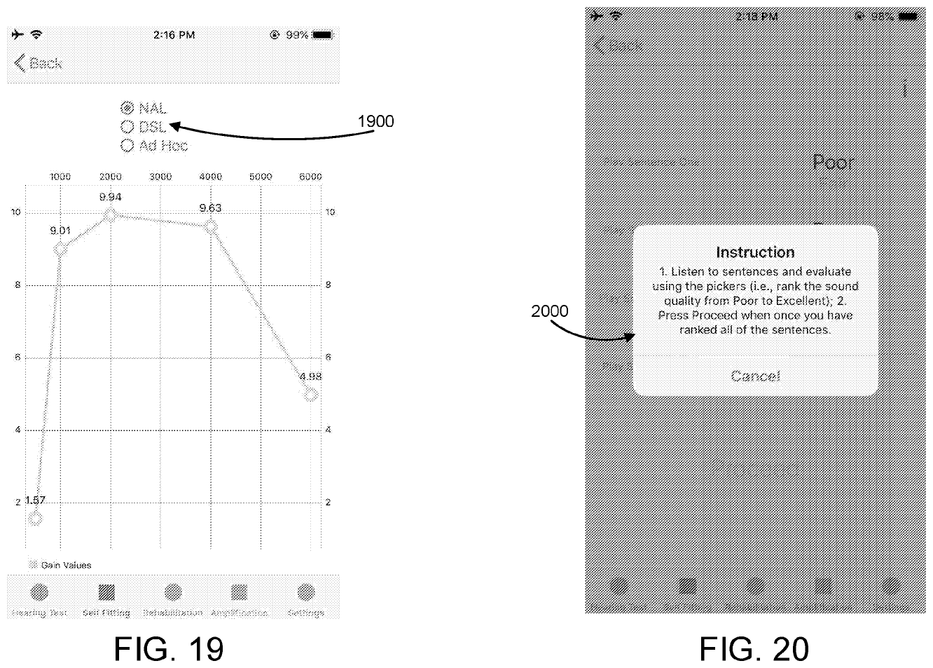

FIG. 19 shows an example a portion of a GUI that can be used to select an initial gain profile in accordance with some embodiments of the disclosed subject matter. In some embodiments, process 300 of FIG. 3 can cause the GUI of FIG. 19 to be presented at 306. In some embodiments, the GUI can include a user interface element 1900 that can be used to receive an indication of a selection of a fitting technique such as NAL, DSL, Dillon, etc.

FIG. 20 shows an example a portion of a GUI that can be used to present instructions for providing a gain profile rating in accordance with some embodiments of the disclosed subject matter. In some embodiments, process 300 of FIG. 3 can cause the GUI of FIG. 20 to be presented at 308 and/or 310. In some embodiments, the GUI can include an instructions module 2000 that can include instructions on how to conduct a gain profile fitting process.

FIG. 21 shows an example a portion of a GUI that can be used to provide gain profile ratings in accordance with some embodiments of the disclosed subject matter. In some embodiments, process 300 of FIG. 3 can cause the GUI of FIG. 21 to be presented at 310. In some embodiments, the GUI can include user interface elements, such as a user interface element 2100, that can be used to receive multiple indicators of sentence rankings. In some embodiments, the GUI can include a user interface element 2104 that can be used to receive an indication to continue gain profile fitting.

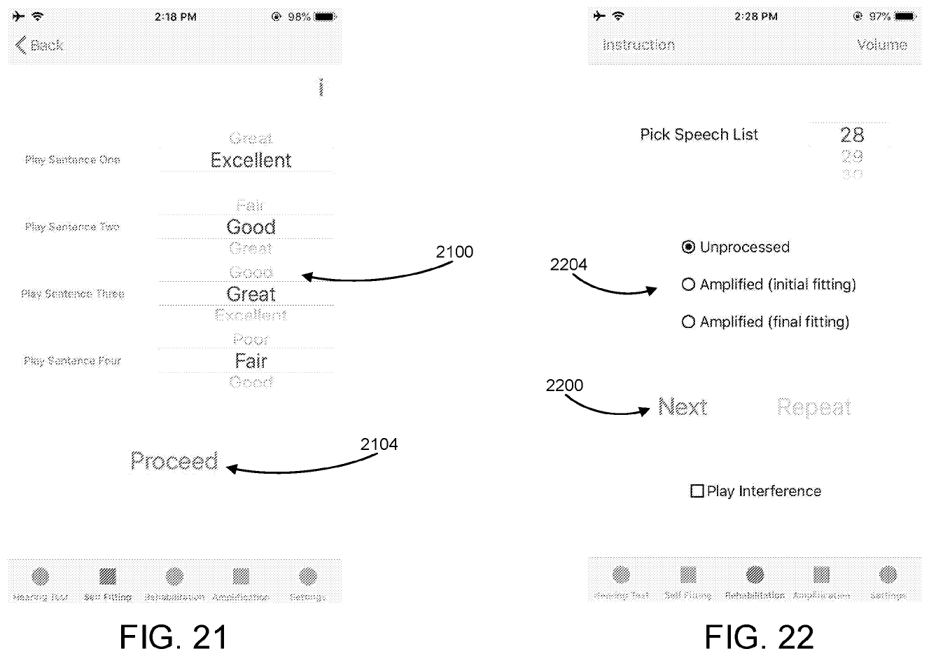

FIG. 22 shows an example a portion of a GUI that can be used to rehabilitate a fitting in accordance with some embodiments of the disclosed subject matter. In some embodiments, process 300 of FIG. 3 can cause the GUI of FIG. 22 to be presented at 314. In some embodiments, the GUI can include a user interface element 2200 that can be used to receive an indication to continue rehabilitating a fitting. In some embodiments, the GUI can include a user interface element 2204 that can be used to receive an indicator of a selected gain profile.

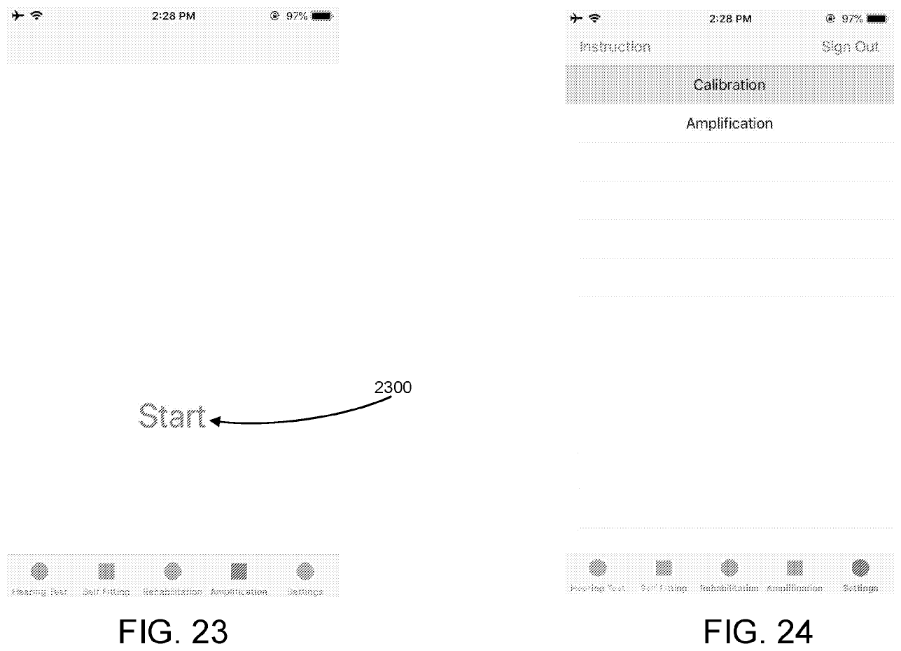

FIG. 23 shows an example a portion of a GUI that can be used to initiate an upload of gain profiles to a personal audio output device in accordance with some embodiments of the disclosed subject matter. In some embodiments, process 300 of FIG. 3 can cause the GUI of FIG. 23 to be presented at 324. In some embodiments, the GUI can include a user interface element 2300 that can be used receive an indication to upload gain profiles to a personal audio output device.

FIG. 24 shows an example a portion of a GUI that can be used to access calibration settings in accordance with some embodiments of the disclosed subject matter. In some embodiments, process 300 of FIG. 3 can cause the GUI of FIG. 24 to be presented at 304.

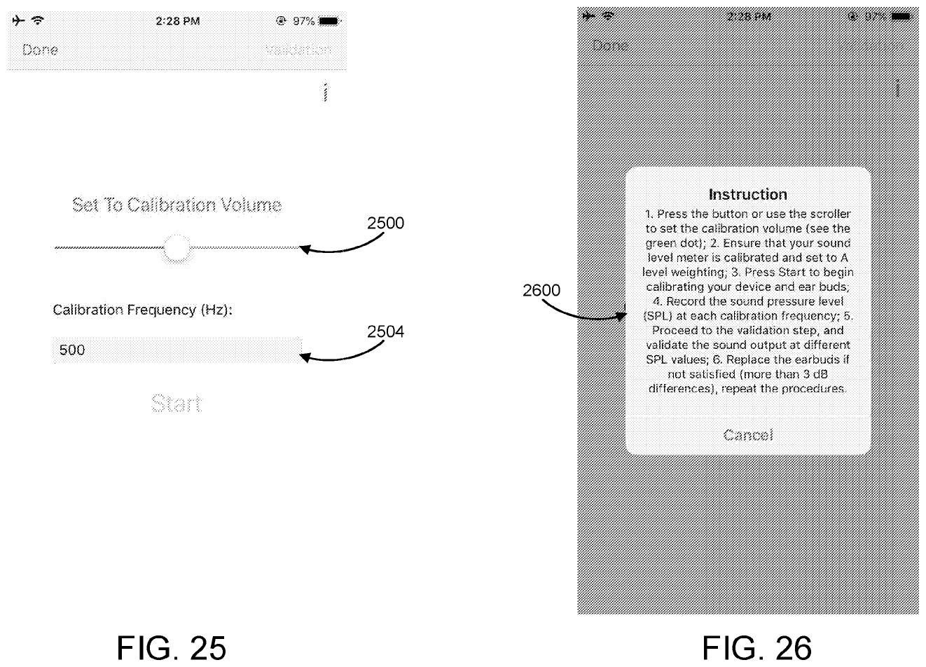

FIG. 25 shows an example a portion of a GUI that can be used to set a calibration volume in accordance with some embodiments of the disclosed subject matter. In some embodiments, process 300 of FIG. 3 can cause the GUI of FIG. 25 to be presented at 304. In some embodiments, the GUI can include a user interface element 2500 (e.g., implemented as a slider) that can be used to receive an indication of a desired calibration volume. In some embodiments, the GUI can include a calibration frequency selection module that can receive an indication of a desired calibration frequency or frequencies.

FIG. 26 shows an example a portion of a GUI that can be used to present instructions for setting a calibration volume in accordance with some embodiments of the disclosed subject matter. In some embodiments, process 300 of FIG. 3 can cause the GUI of FIG. 26 to be presented at 304. In some embodiments, the GUI can include an instructions module 2600 that includes instructions on how to perform calibration.

In some embodiments, any suitable computer readable media can be used for storing instructions for performing the functions and/or processes described herein. For example, in some embodiments, computer readable media can be transitory or non-transitory. For example, non-transitory computer readable media can include media such as magnetic media (such as hard disks, floppy disks, etc.), optical media (such as compact discs, digital video discs, Blu-ray discs, etc.), semiconductor media (such as RAM, Flash memory, electrically programmable read only memory (EPROM), electrically erasable programmable read only memory (EEPROM), etc.), any suitable media that is not fleeting or devoid of any semblance of permanence during transmission, and/or any suitable tangible media. As another example, transitory computer readable media can include signals on networks, in wires, conductors, optical fibers, circuits, or any suitable media that is fleeting and devoid of any semblance of permanence during transmission, and/or any suitable intangible media.

It should be noted that, as used herein, the term mechanism can encompass hardware, software, firmware, or any suitable combination thereof.

It should be understood that the above described steps of the process of FIG. 3 can be executed or performed in any order or sequence not limited to the order and sequence shown and described in the figures. Also, some of the above steps of the process of FIG. 3 can be executed or performed substantially simultaneously where appropriate or in parallel to reduce latency and processing times.

Although the invention has been described and illustrated in the foregoing illustrative embodiments, it is understood that the present disclosure has been made only by way of example, and that numerous changes in the details of implementation of the invention can be made without departing from the spirit and scope of the invention, which is limited only by the claims that follow. Features of the disclosed embodiments can be combined and rearranged in various ways.

What is claimed is:

1. A system for automatically determining audio gain profiles, the system comprising:
a computing device comprising at least one processor and a memory, the computing device being in communication with a personal audio output device comprising a speaker, wherein the at least one processor is configured to execute a process comprising:
determining a plurality of hearing thresholds based on inputted responses to emitted tones;
determining a plurality of gain profiles, each of the plurality of gain profiles based on the plurality of hearing thresholds, each gain profile including a set of gain values;
(a) generating a plurality of augmented audio signals by using each of the plurality of gain profiles to augment an audio signal;
(b) causing each of the plurality of augmented audio signals to be presented using the speaker;
(c) receiving a gain profile rating associated with each of the plurality of gain profiles responsive to causing each of the plurality of augmented audio signals to be presented;
(d) determining for each of the plurality of gain profiles a fitness value based on the respective gain profile rating;
(e) determining whether a stopping condition has been satisfied;
(f) generating a new generation of gain profiles based on fitness values associated with the plurality of gain profiles, wherein each gain profile included in the new generation of gain profiles comprises a plurality of bits representing the set of gain values;
(g) in response to determining that at least one stopping condition has not been satisfied, augmenting the new generation of gain profiles by exchanging a string of bits representing at least a portion of one or more gain values in a first gain profile included in the new generation of gain profiles with a corresponding string of bits included in a second gain profile included in the new generation of gain profiles;
repeating (a) to (g) until at least one stopping condition has been satisfied at (e) using the new generation of gain profiles generated at (f) and augmented at (g) as the plurality of gain profiles at (a);
in response to determining that at least one stopping condition has been satisfied, determining a final gain profile based on the fitness values of the plurality of gain profiles; and
outputting the final gain profile to the personal audio output device.

2. The system of claim 1, wherein augmenting the new generation of gain profiles further comprises:
randomly mutating at least one bit of a gain value included in one of the gain profiles included in the new generation of gain profiles.

3. The system of claim 1, wherein generating the new generation of gain profiles based on the fitness comprises:
performing a plurality of weighted random selections from the plurality of gain profiles with weights based on the fitness value associated with each of the plurality of gain profiles to populate the new generation of gain profiles.

4. The system of claim 1, wherein the audio signal comprises a sentence, and
wherein causing each of the plurality of augmented audio signals to be presented using the speaker comprises:
causing the sentence to be audibly output by the speaker based on a first gain profile of the plurality of gain profiles; and
causing the sentence to be audibly output based on a second gain profile of the plurality of gain profiles, wherein the first current gain profile is associated with a first gain profile rating and the second current gain profile is associated with a second gain profile rating.

5. The system of claim 4, wherein the gain profile ratings are discrete values selected from a predetermined range of values.

6. The system of claim 4, wherein the computing device comprises a smartphone,
wherein (a) further comprises:
retrieving an audio file of the sentence from the memory; and
augmenting the audio file based on the first gain profile to produce a first augmented audio signal, and
wherein (b) further comprises:
providing the first augmented audio signal to the personal audio output device, thereby causing the sentence to be audibly output by the speaker.

7. The system of claim 1, wherein the personal audio output device comprises a personal sound amplification product.

8. A method for automatically determining audio gain profiles, the method comprising:
determining a plurality of hearing thresholds based on inputted responses to emitted tones;
determining a plurality of gain profiles, each of the plurality of gain profiles based on the plurality of hearing thresholds, each gain profile including a set of gain values;
(a) generating a plurality of augmented audio signals by using each of the plurality of gain profiles to augment an audio signal;
(b) causing each of the plurality of augmented audio signals to be presented using a speaker of a personal audio output device;
(c) receiving, via a user interface, a gain profile rating associated with each of the plurality of gain profiles responsive to causing each of the plurality of augmented audio signals to be presented;
(d) determining for each of the plurality of gain profiles a fitness value based on the respective gain profile rating;
(e) determining whether a stopping condition has been satisfied;
(f) generating a new generation of gain profiles based on fitness values associated with the plurality of gain profiles, wherein each gain profile included in the new generation of gain profiles comprises a plurality of bits representing the set of gain values;
(g) in response to determining that at least one stopping condition has not been satisfied, augmenting the new generation of gain profiles by exchanging a string of bits representing at least a portion of one or more gain values in a first gain profile included in the new generation of gain profiles with a corresponding string of bits included in a second gain profile included in the new generation of gain profiles;
repeating (a) to (g) until at least one stopping condition has been satisfied at (e) using the new generation of gain profiles generated at (f) and augmented at (g) as the plurality of gain profiles at (a);
in response to determining that at least one stopping condition has been satisfied, determining a final gain profile based on the fitness values of the plurality of gain profiles; and
outputting the final gain profile to the personal audio output device.

9. The method of claim 8, wherein augmenting the new generation of gain profiles further comprises:
randomly mutating at least one bit of a gain value included in one of the gain profiles included in the new generation of gain profiles.

10. The method of claim 8, wherein generating the new generation of gain profiles based on the fitness comprises:
performing a plurality of weighted random selections from the plurality of gain profiles with weights based on the fitness value associated with each of the plurality of gain profiles to populate the new generation of gain profiles.

11. The method of claim 8, wherein the audio signal comprises a sentence, and
wherein causing each of the plurality of augmented audio signals to be presented using the speaker comprises:
causing the sentence to be audibly output by the speaker based on a first gain profile of the plurality of gain profiles; and
causing the sentence to be audibly output based on a second gain profile of the plurality of gain profiles, wherein the first current gain profile is associated with a first gain profile rating and the second current gain profile is associated with a second gain profile rating.

12. The method of claim 11, wherein the gain profile ratings are discrete values selected from a predetermined range of values.

13. The method of claim 11, wherein the user interface is presented using a smartphone,
wherein (a) further comprises:
retrieving an audio file of the sentence from a memory of the smartphone; and
augmenting the audio file based on the first gain profile to produce a first augmented audio signal, and
wherein (b) further comprises:
providing, from the smartphone, the first augmented audio signal to the personal audio output device, thereby causing the sentence to be audibly output by the speaker.

14. The method of claim 8, wherein the personal audio output device comprises a personal sound amplification product.

15. A non-transitory computer readable medium containing computer executable instructions that, when executed by a processor, cause the processor to perform a method for automatically determining audio gain profiles, the method comprising:
determining a plurality of hearing thresholds based on inputted responses to emitted tones;
determining a plurality of gain profiles, each of the plurality of gain profiles based on the plurality of hearing thresholds, each gain profile including a set of gain values;
(a) generating a plurality of augmented audio signals by using each of the plurality of gain profiles to augment an audio signal;
(b) causing each of the plurality of augmented audio signals to be presented using a speaker of a personal audio output device;
(c) receiving, via a user interface, a gain profile rating associated with each of the plurality of gain profiles responsive to causing each of the plurality of augmented audio signals to be presented;
(d) determining for each of the plurality of gain profiles a fitness value based on the respective gain profile rating;
(e) determining whether a stopping condition has been satisfied;
(f) generating a new generation of gain profiles based on fitness values associated with the plurality of gain profiles, wherein each gain profile included in the new generation of gain profiles comprises a plurality of bits representing the set of gain values;
(g) in response to determining that at least one stopping condition has not been satisfied, augmenting the new generation of gain profiles by exchanging a string of bits representing at least a portion of one or more gain values in a first gain profile included in the new generation of gain profiles with a corresponding string of bits included in a second gain profile included in the new generation of gain profiles;
repeating (a) to (g) until at least one stopping condition has been satisfied at (e) using the new generation of gain profiles generated at (f) and augmented at (g) as the plurality of gain profiles at (a);
in response to determining that at least one stopping condition has been satisfied, determining a final gain profile based on the fitness values of the plurality of gain profiles; and
outputting the final gain profile to the personal audio output device.

16. The non-transitory computer readable medium of claim 15, wherein augmenting the new generation of gain profiles further comprises:
randomly mutating at least one bit of a gain value included in one of the gain profiles included in the new generation of gain profiles.

17. The non-transitory computer readable medium of claim 15, wherein generating the new generation of gain profiles based on the fitness comprises:
performing a plurality of weighted random selections from the plurality of gain profiles with weights based on the fitness value associated with each of the plurality of gain profiles to populate the new generation of gain profiles.

18. The non-transitory computer readable medium of claim 15, wherein the audio signal comprises a sentence, and
wherein causing each of the plurality of augmented audio signals to be presented using the speaker comprises:
causing the sentence to be audibly output by the speaker based on a first gain profile of the plurality of gain profiles; and
causing the sentence to be audibly output based on a second gain profile of the plurality of gain profiles, wherein the first current gain profile is associated with a first gain profile rating and the second current gain profile is associated with a second gain profile rating.

19. The non-transitory computer readable medium of claim 18, wherein the gain profile ratings are discrete values selected from a predetermined range of values.

20. The non-transitory computer readable medium of claim 18, wherein the user interface is presented using a smartphone,
wherein (a) further comprises:
retrieving an audio file of the sentence from a memory of the smartphone; and
augmenting the audio file based on the first gain profile to produce a first augmented audio signal, and
wherein (b) further comprises:
providing, from the smartphone, the first augmented audio signal to the personal audio output device, thereby causing the sentence to be audibly output by the speaker.

21. The non-transitory computer readable medium of claim 15, wherein the personal audio output device comprises a personal sound amplification product.
